(19) United States
(12) Patent Application Publication
(10) Pub. No.: US 2008/0108181 A1
(43) Pub. Date: May 8, 2008

(54) METHOD FOR ATTACHING INTEGRATED CIRCUIT COMPONENT TO A SUBSTRATE

(75) Inventors: Yan Cheong CHAN, Hong Kong (CN); Sai Choo TAN, Pekan Pahang (MY)

Correspondence Address: HESLIN ROTHENBERG FARLEY & MESITI PC, 5 COLUMBIA CIRCLE, ALBANY, NY, 12203, US

(73) Assignee: CITY UNIVERSITY OF HONG KONG, Hong Kong (CN)

(21) Appl. No.: 11/556,887

(22) Filed: Nov. 6, 2006

(51) Int. Cl. H01L 21/00

(52) U.S. Cl. 438/119

(57) ABSTRACT

An integrated circuit component is attached to a substrate by dispensing a controlled amount of photo-activatable anisotropic conductive adhesive (ACA) at a desired location on the substrate, exposing the dispensed ACA to an electromagnetic radiation source to initiate a chemical reaction in the ACA, aligning the component with the substrate such that a bond pad on the component faces the dispensed ACA, bonding the component to the substrate under a low pressure loading, and heating the bonded component and substrate.

### FIELD OF THE INVENTION

This invention relates to a method of attaching an integrated circuit component to a substrate, and in particular to a method for attaching an integrated circuit (IC) component such as a memory chip or a RFID (radio-frequency identification device) to a smart card.

### BACKGROUND OF THE INVENTION

There are an increasing number of applications in which it is desired to fix an IC component such as a memory chip, RFID chip or other form of IC component to a substrate, usually a relatively thin plastics substrate. Such applications include credit cards, debit cards, identity cards, stored value cards, security passes and the like. Such devices are generally known as “smart cards”. They are conventionally about the size of a credit card (i.e., no more than about 9 cm by 6 cm say), and preferably should not be significantly thicker than a conventional credit card so that a smart card can be kept with conventional credit cards and other such cards in a wallet or card holder without any inconvenience.

The IC component may have a varying degree of processing power ranging from a simple memory chip through to an IC chip capable of processing inputs. Typical functions of the IC component include data storage, data receiving, and data transmission. In all cases, however, the chip must be secured both physically and electrically to the card, which could be a paper-based card though is more normally formed of plastics. The IC component may be electrically connected to conductive tracks which are electroplated or screen-printed on the substrate. For optimum results there are a number of desired features to any chosen method for fabricating such a smart card. The resulting card should not be unduly thick, the fabrication process should not damage either the substrate or the IC component, and the fabrication process should be quick and preferably low-cost.

One known method of fixing an IC component to a substrate includes the use of wire bonding techniques as illustrated in FIG. 1. Wire bonding is used where an IC component is electrically connected to a connection area on the substrate through a thermosonic wire bond. Referring to FIG. 1 an IC component such as a memory chip 6 is attached to a substrate 5 through adhesive bonding. A tape or passive layer 4 is laminated onto the metallized surface of the substrate 5 in order to build an electrical circuit pattern on the substrate. Gold wires 2 are then bonded to form electrical connections from active areas 3 on the memory chip 6 to exposed conductive areas of the substrate surface. After high-temperature (approx. 200° C.) thermosonic bonding of the gold wires 2 between the memory chip 6 and the substrate 5, an epoxy material 1 is dispensed over the area defined by the memory chip 6 and the electrical connections to the substrate 5 in order to encapsulate the memory chip 6 and the connections in order to protect them from damage and degradation. The epoxy material is cured at 150° C. for about 30 minutes.

There are a number of disadvantages with this prior art method. The process cycle is quite long not least because only one input/output wire bond can be formed at one time and this increases the total processing time. The thickness of the resulting smart card is also relatively large, partly because of the height of the loops of gold wire 2 forming the connections which may be about 200 μm) and the use of the epoxy encapsulant further increases the thickness and total dimensions of the resulting smart card. The card may be at least 600 μm thick and may be as thick as about 760 μm.

Also known in the art is flip chip technology using either isotropic conductive adhesives (ICA) or anisotropic conductive adhesives (ACA). Such techniques are known as “flip chip” because the IC component is turned so that the conductive pads face the substrate as opposed to the technique shown in FIG. 1 in which the conductive areas 3 face away from the substrate. In both ICA and ACA techniques the IC component is fixed to the substrate by a conductive adhesive that provides both the physical and electrical connection.

FIG. 2 shows an example of a prior art ICA technique. An IC component such as a memory chip 7 is electrically connected to the substrate 12 through the use of an isotropic conductive adhesive 9. The ICA 9 is screen-printed at the connection regions of the substrate 12, and the memory chip 7 is then mounted and bonded with the bond pads 8 of the chip 7 aligned with contact areas 10 on the substrate. The ICA 9 is then pre-cured at 150° C. for 1 minute until the memory chip 7 will at least hold in a stable position on the substrate 12. Subsequently an epoxy underfill 11 is filled into the space between the memory chip 7 and the substrate 12 by capillary action to serve as a stable mechanical protective layer. The memory chip 7 is bonded to the substrate 12 with a mounting time of 6±3 seconds and at a pressure of 4±3N. The bonded sample is then post-heated in an oven at 150° C. or below for 2 minutes or above until the final mechanical and electrical properties are achieved. This method, however, includes a number of processing steps including the screen printing of the ICA on the substrate, mounting of the memory chip, pre-curing of the ICA, and curing of the epoxy underfill. The method does reduce the total thickness of the finished smart card to about 500 μm, but the total processing time exceeds 1 hour.

FIG. 3 shows a prior art method using an anisotropic conductive film (ACF). ACF is an epoxy matrix 17 filled with conductive particles 15 which may be gold, nickel, or polymer beads coated with gold and/or nickel. An IC component such as a memory chip 13 is attached to a contact area on a substrate 18. Electrical connections are formed by the entrapment of electrically conductive particles 15 between the bond pads or bumps 14 formed on the memory chip 13, and the electrodes 16 formed on the substrate 18. The ACF epoxy matrix 17 will act as a protective layer.

The use of ACF has the advantage that it forms the electrical connection path and provides mechanical stability in a single process step. The interconnections are formed when the conductive particles 15 are compressed and deformed in the area between the active areas 14 on the chip 17, and the electrodes 16 on the substrate. The thermal loading is about 200° C. for about 10 s, and with the ACF being compressed to about 20 μm or less both the thickness (the total thickness may be about 450 μm) and the processing time may be reduced. The disadvantage of this method, however, is that it requires a high pressure loading up to 100 Mpa or above to form the electrical connections.

### SUMMARY OF THE INVENTION

According to the present invention there is provided a method of attaching an integrated circuit component to a substrate. The method comprises dispensing a controlled amount of photo-activatable anisotropic conductive adhesive (ACA) at a desired location on said substrate, exposing said dispensed ACA to electromagnetic radiation source to initiate a chemical reaction in said ACA, aligning said component with said substrate such that a bond pad on said component faces said dispensed ACA, bonding said component to said substrate under a low pressure loading, and heating said bonded component and substrate.

Preferably the electromagnetic radiation is UV radiation, for example the radiation may be at a wavelength of between about 250 nm to about 400 nm. The electromagnetic radiation may have an intensity of about 140 mW/cm²±about 60 mW/cm² (i.e., about 80 mW/cm² to about 200 mW/cm²).

Preferably the low pressure loading is about 4N±about 3N and is held for a loading time of about 6 seconds±about 3 seconds. The heating may comprise heating in an oven at a temperature of less than about 150° C., and the heating may be carried out for at least about 2 minutes.

The ACA may comprise conductive particles within an epoxy matrix and wherein said conductive particles have a diameter of about 6 μm±about 2 μm.

The method may be applied to the manufacture of a smart card, for example where the integrated circuit is a memory chip and the substrate comprises an antenna. In such an embodiment the memory chip has a length and width both of which are less than about 1.5 mm and a wafer thickness of about 150 μm±about 50 μm, and the memory chip is formed with bond pads having a thickness of about 18 μm±about 5 μm. The substrate may be formed with conductive tracks and wherein the bond pads of said memory chip are connected to connection points of the conductive tracks. The conductive tracks may be formed by electroplating copper or aluminium onto said substrate, or by screen printing with a silver paste polymer, and may form the antenna of an RFID smart card.

### BRIEF DESCRIPTION OF THE DRAWINGS

Some embodiments of the invention will now be described by way of example and with reference to the accompanying drawings, in which:—

FIG. 1 shows in cross-section a smart card formed by a conventional method using wire bonding,

FIG. 2 shows in cross-section a smart card formed by a conventional method using isotropic conductive adhesive,

FIG. 3 shows in cross-section a smart card formed by a conventional method using an anisotropic conductive film,

FIG. 4 shows the dispensing of UV activated ACA in an embodiment of the invention,

FIG. 5 shows an enlarged view of the UV activated ACA in an embodiment of the invention, and

FIG. 6 is a cross-section through a smart card formed according to an embodiment of the invention.

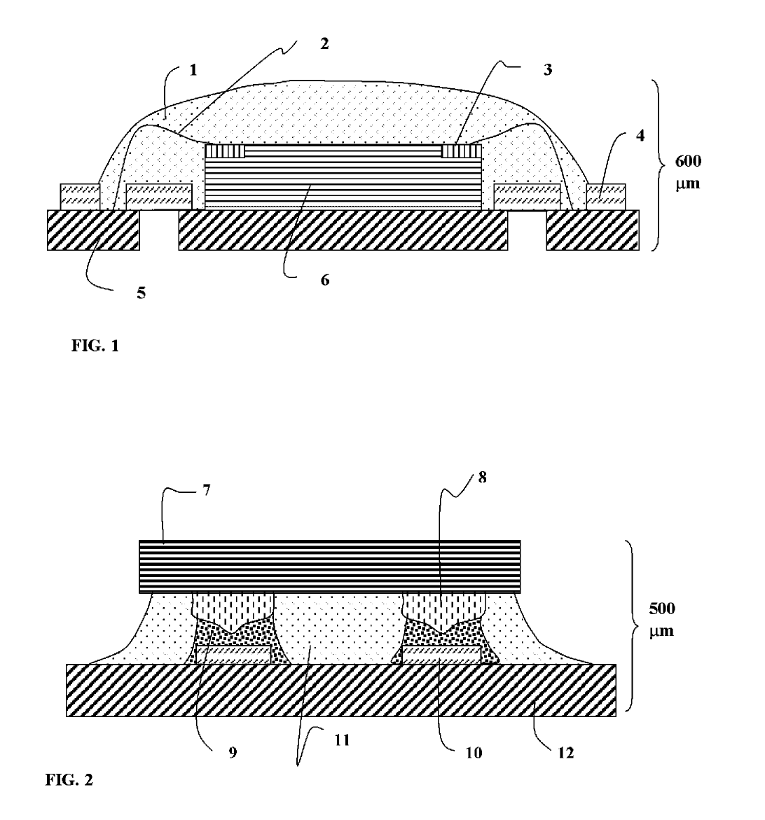

### DETAILED DESCRIPTION OF PREFERRED EMBODIMENTS

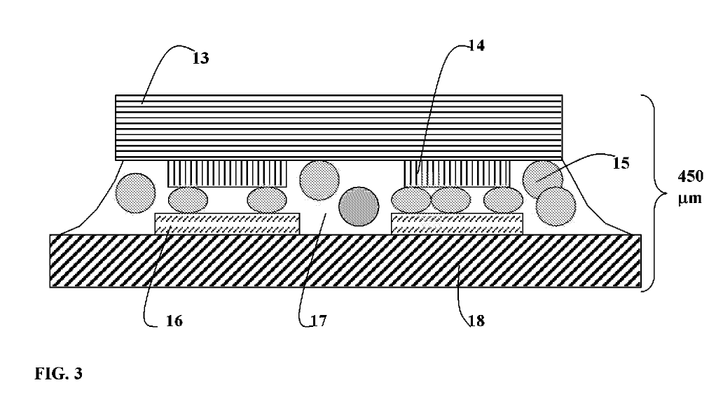

The present invention, at least in its preferred forms, provides a method of fabricating a smart card in which the IC component (e.g., a memory chip) is attached to the substrate (e.g., a chip carrier) using UV-activated ACA. UV-activated ACAs comprise conductive particles in an epoxy resin with the addition of a UV photo-initiator. The technique is similar to the above-described prior art method using a heat-cured ACF as described with reference to FIG. 3, at least to the extent that metal or metal-coated polymer particles in the ACA will form the electrical connection between the memory chip and the connections on the substrate. However, the method of the present invention uses UV-activated ACAs which need to be exposed to UV (or a light spectrum within a certain wavelength) for a few seconds to initiate and activate the necessary chemical reaction. Although this UV-activation implies an additional processing step, the advantage of using UV-activated ACAs is that the method allows the use of low-cost materials for the substrate such as PET and PVC, and the use of copper and aluminium and other less noble metals, since the processing parameters such as temperature and pressure are less severe and therefore less demanding on the choice of materials.

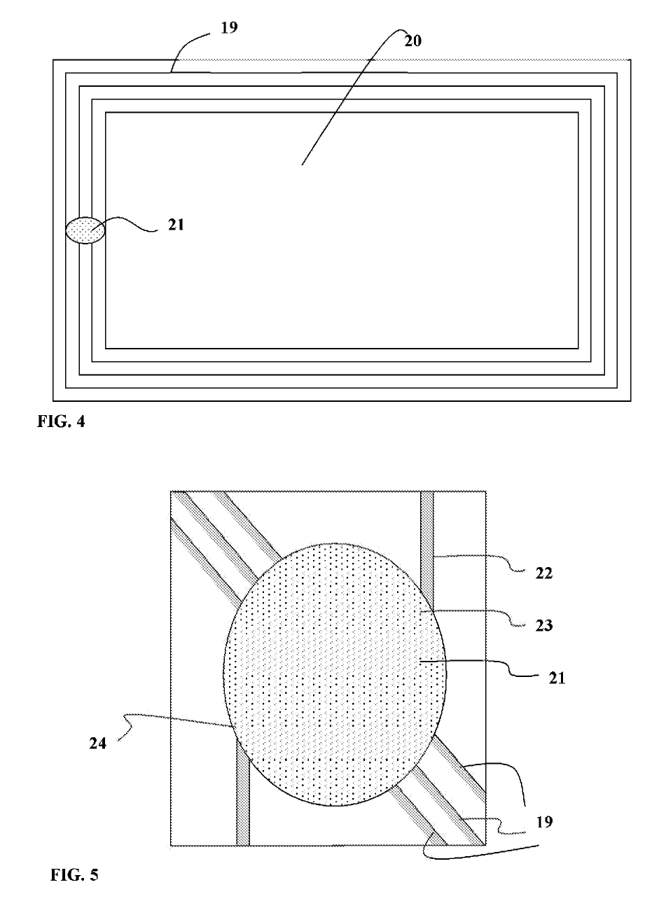

In FIGS. 4 to 6 an embodiment of the invention will be described in which an IC component in the form of a chip 25 is to be fixed to a substrate 20 (70 mm by 80 mm) as part of a contactless RFID smart card. A typical size for the chip may have a length and width less than about 1 mm, and a thickness of about 150 μm±about 50 μm. In such an embodiment the chip 25 is electrically connected to windings that extend around the edges of the rectangular substrate 20 and form an antenna 19 (FIG. 4). The antenna windings may, however, be square, rectangular or circular depending upon the desired application. The antenna windings are preferably formed of less noble metals than gold and silver, such as copper, aluminium or silver paste. The substrate is preferably formed from low cost plastics materials such as PVC, PET and other low T_{g} materials which are cheaper than popularly used fiber glass (FR4) or polyimide (PI) though of course such more expensive materials could be used if desired.

As can be seen from FIG. 4, an amount of UV-activated ACA 21 is provided at one end of the substrate 20 in the region of the windings 19 and this will be described in more detail with reference to the enlarged view of FIG. 5. An example of a suitable form of UV-activated ACA is DELO ACAbond UV-activated ACA. This is an adhesive comprising conductive particles with the size of the particles being around 6.5 μm and the density of particles being around 1200/mm².

Referring to FIG. 5 the ACA 21 is dispensed so as to contact connections 23, 24 of the antenna windings and also to cover individual windings shown by reference number 19 in FIG. 5. The ACA 21 should be provided at this connection part of the substrate in order to form the necessary connections between the chip 25 and the antenna 19. The amount of ACA used and the spot size is controlled by a dispenser. The amount of ACA and the spot size needed will depend on the pitch between the connections 23, 24. Sufficient ACA should be provided to make the necessary connections, but too much ACA should be avoided as it may contaminate the bond head which is used to hold the chip 25. The ACA is exposed to light with a spectrum of from about 250 nm to about 400 nm for a short period of time (e.g., about 5 s±about 3 s) at an intensity of about 140 mW/cm²±about 60 mW/cm² to activate the photo-initiators in the ACA.

The substrate 20 is then placed on the chuck table of a flip chip bonder, and a chip 25 (typically with length and width dimensions no greater than about 1.5 mm, a wafer thickness of about 150 μm±about 50 μm and a bond pad thickness of about 18 μm±about 5 μm) is placed on the bond head and is aligned such that connection bond pads 26 formed on the chip 25 match connections 23, 24 on the substrate 20. The chip 25 is then mounted and bonded at a low bonding pressure of less than about ION, preferably about 4N±about 3N, for a loading time of about 6 s±about 3 s, and the UV-activated ACA is then post-heated at less than about 150° C. for at least about 2 minutes until the desired mechanical and electrical properties are achieved. A smart card with a thickness of about 390 μm can be achieved in this way.

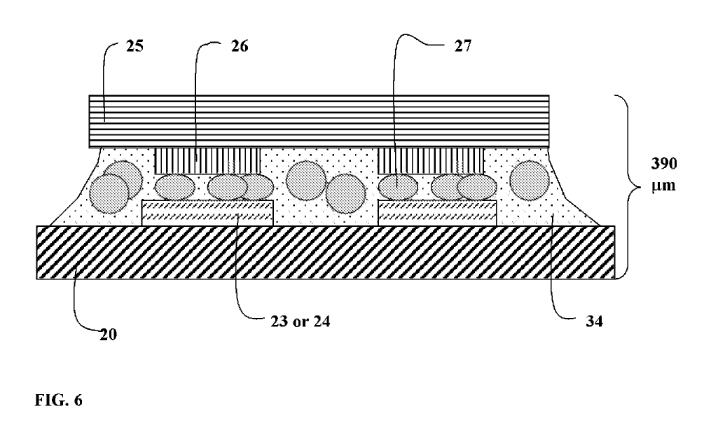

FIG. 6 shows the cross-section of the connection between the chip 25 and the substrate 20 in more detail. The electrical connection path is established through the contact of conductive particles 27 present in the ACA between the bond pads 26 on the chip 25 and the connections 23, 24 of the antenna 19. The conductive particles may have a diameter of about 6 μm±about 2 μm. The epoxy material 34 provides mechanical strength and stability to the connection between the chip 25 and the substrate 20.

A significant advantage of the present invention, at least in its preferred forms, is that by the use of UV-activated ACA both low bonding pressures and low process temperatures are employed. This enables the method to be used with cheaper materials for the substrate and for the electrical connections and conductive tracks as they do not have to withstand high temperatures and/or pressures as in the prior art.

1. A method of attaching an integrated circuit IC component to a substrate, the method comprising:
dispensing a controlled amount of photo-activatable anisotropic conductive adhesive (ACA) at a desired location on said substrate;
exposing said dispensed ACA to an electromagnetic radiation source to initiate a chemical reaction in said ACA;
aligning said IC component with said substrate such that a bond pad on said IC component faces said dispensed ACA;
bonding said IC component to said substrate under a low pressure loading; and
heating said bonded IC component and substrate.

2. The method of claim 1, wherein said electromagnetic radiation comprises UV radiation.

3. The method of claim 1, wherein said electromagnetic radiation has a wavelength of between about 250 nm to about 400 nm.

4. The method of claim 1, wherein said electromagnetic radiation has an intensity of about 140 mW/cm²±about 60 mW/cm².

5. The method of claim 1, wherein the low pressure loading comprises loading at about 4N±about 3N for a loading time of about 6 seconds±about 3 seconds.

6. The method of claim 1, wherein the heating comprises heating at a temperature of less than about 150° C.

7. The method of claim 1, wherein the heating comprises heating for at least about 2 minutes.

8. The method of claim 1, wherein said ACA comprises conductive particles within an epoxy matrix, and wherein said conductive particles have a diameter of about 6 μm±about 2 μm

9. The method of claim 1, wherein said IC component comprises a memory chip, and wherein said substrate comprises an antenna.

10. The method of claim 9, wherein said memory chip has a length and width both of which are less than about 1.5 mm and a wafer thickness of about 150 μm±about 50 μm, and wherein said memory chip is formed with bond pads having a thickness of about 18 μm±about 5 μm.

11. The method of claim 10, wherein said substrate comprises one or more conductive tracks, and wherein the bond pads of said memory chip are coupled to connection points of said conductive tracks.

12. The method of claim 11, wherein said conductive tracks are formed by electroplating copper or aluminium onto said substrate.

13. The method of claim 11, wherein said conductive tracks are formed by screen printing with a silver paste polymer.

14. The method of claim 11, wherein said conductive tracks form the antenna of an RFID smart card.
